(19) United States
(12) Patent Application Publication
(10) Pub. No.: US 2024/0006516 A1
(43) Pub. Date: Jan. 4, 2024

(54) THIN FILM TRANSISTOR AND MANUFACTURING METHOD THEREOF

(71) Applicant: Electronics and Telecommunications Research Institute, Daejeon (KR)

(72) Inventors: Yong Hae KIM, Daejeon (KR); Chi-Sun HWANG, Daejeon (KR); Jong-Heon YANG, Daejeon (KR)

(73) Assignee: Electronics and Telecommunications Research Institute, Daejeon (KR)

(21) Appl. No.: 18/321,433

(22) Filed: May 22, 2023

(30) Foreign Application Priority Data
Jun. 29, 2022 (KR) 10-2022-0079625

(51) Int. Cl. H01L 29/66; H01L 29/786

(52) U.S. Cl. CPC H01L 29/66969; H01L 29/78642; H01L 29/78696; H01L 29/7869

(57) ABSTRACT

An embodiment of the inventive concept provides a thin film transistor and a manufacturing method of the same. The manufacturing method includes forming a data electrode on one side of a substrate, forming a spacer layer on a portion of the data electrode and the other side of the substrate, forming a drain electrode on a top surface of the spacer layer, forming an active layer on a sidewall of the spacer layer, the drain electrode, and the data electrode, forming a gate insulation film that covers the active layer on the sidewall of the spacer layer, and forming a doped layer on the gate insulation film and the active layer outside the gate insulation film to form impurity regions at both sides, respectively, of the active layer.

### CROSS-REFERENCE TO RELATED APPLICATIONS

This U.S. non-provisional patent application claims priority under 35 U.S.C. § 119 of Korean Patent Application No. 10-2022-0079625, filed on Jun. 29, 2022, the entire contents of which are hereby incorporated by reference.

### BACKGROUND

The present disclosure herein relates to a thin film transistor and a manufacturing method thereof, and more particularly, to an oxide semiconductor thin-film transistor and a manufacturing method thereof.

In general, thin film transistors may have an impurity region between source/drain electrodes and an active layer. The impurity region may reduce or remove contact resistance between the source/drain electrodes and the active layer. Nevertheless, oxide thin-film transistors may be manufactured by using a self-doped state thereof without a separate impurity region. Oxide thin-film transistors having a vertical channel require the impurity region.

### SUMMARY

The present disclosure provides a method of manufacturing a thin film transistor capable of increasing productivity.

An embodiment of the inventive concept provides a thin film transistor manufacturing method. The manufacturing method includes forming a data electrode on one side of a substrate, forming a spacer layer on a portion of the data electrode and the other side of the substrate, forming a drain electrode on a top surface of the spacer layer, forming an active layer on a sidewall of the spacer layer, the drain electrode, and the data electrode, forming a gate insulation film exposing the active layer on the drain electrode and the data electrode and covering the active layer on the sidewall of the spacer layer, and forming a doped layer on the gate insulation film and the active layer outside the gate insulation film to form impurity regions at both sides, respectively, of the active layer.

In an embodiment, the gate insulation film may be formed using a self-alignment method.

In an embodiment, the gate insulation film may include a silicon oxide.

In an embodiment, the doped layer may include a metal oxide or semiconductor oxide containing hydrogen ions or hydrogen molecules.

In an embodiment, the metal oxide may include an aluminum oxide.

In an embodiment, the semiconductor oxide may include a silicon oxide.

In an embodiment, the impurity regions may contain hydrogen ions or hydrogen molecules.

In an embodiment, the spacer layer may include a silicon oxide or a silicon nitride.

In an embodiment, the active layer may include an indium gallium zinc oxide.

In an embodiment, the thin film transistor manufacturing method may further include forming a gate electrode on the doped layer.

In an embodiment of the inventive concept, a thin film transistor manufacturing method includes forming a data electrode on one side of a substrate, forming a first spacer layer on a portion of the data electrode and the other side of the substrate, forming a gate electrode on a top surface of the first spacer layer, forming a second spacer layer on the gate electrode and the first spacer layer, forming a drain electrode on a top surface of the second spacer layer, forming a gate insulation film on a sidewall of each of the first spacer layer, the gate electrode, the second spacer layer, and the drain electrode, and the data electrode, forming an active layer on the gate insulation film, the data electrode, and the drain electrode, forming a doped barrier layer exposing the active layer on the drain electrode and the data electrode and covering the active layer on the spacer layers, and forming a doped layer on the doped barrier layer, the active layer outside the doped barrier layer, and the drain electrode to form impurity regions on the active layer outside the doped barrier layer.

In an embodiment, the gate insulation film may be formed using a self-alignment method.

In an embodiment, the doped barrier layer may be formed using a self-alignment method.

In an embodiment, the doped barrier layer may include a silicon nitride or a metal oxide.

In an embodiment, the impurity regions may contain hydrogen ions or hydrogen molecules.

In an embodiment of the inventive concept, a thin film transistor includes a data electrode disposed on one side of a substrate, a spacer layer disposed on a portion of the data electrode and the other side of the substrate, a drain electrode disposed on a top surface of the spacer layer, an active layer disposed on a sidewall of each of the spacer layer and the drain electrode, and the data electrode, a gate insulation film disposed on an upper portion or lower portion of the active layer on the sidewall of each of the spacer layer and the drain electrode, impurity regions, each of which is connected to the active layer at each of both sides of the gate insulation film, and a doped layer disposed on the impurity regions and the active layer.

In an embodiment, the thin film transistor may further include a gate electrode disposed on the doped layer.

In an embodiment, the spacer layer may include a first spacer layer and a second spacer layer disposed on the first spacer layer.

In an embodiment, the thin film transistor may further include a gate electrode disposed between the first spacer layer and the second spacer layer.

In an embodiment, the thin film transistor may further include a doped barrier layer disposed between the active layer and the doped layer that are between the impurity regions.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 illustrates an example of a thin film transistor according to an embodiment of the inventive concept;

FIG. 2 is a flowchart illustrating a method of manufacturing the thin film transistor in FIG. 1;

FIGS. 3 to 7 are cross-sectional views illustrating operations of a method of manufacturing the thin film transistor in FIG. 1;

FIG. 8 illustrates an example of a thin film transistor according to an embodiment of the inventive concept;

FIG. 9 is a flowchart illustrating a method of manufacturing the thin film transistor in FIG. 8; and

FIGS. 10 to 15 are cross-sectional views illustrating operations of a method of manufacturing the thin film transistor in FIG. 8.

### DETAILED DESCRIPTION

Hereinafter, embodiments of the inventive concept will be described in detail with reference to the accompanying drawings. Advantages and features of the present invention, and implementation methods thereof will be clarified through following embodiments described with reference to the accompanying drawings. The inventive concept may, however, be embodied in different forms and should not be construed as limited to the embodiments set forth herein. Rather, these embodiments are provided so that this disclosure will be thorough and complete, and will fully convey the scope of the present invention to those skilled in the art. Further, the present invention is only defined by scopes of claims. Like reference numerals refer to like elements throughout.

The terminology used herein is for the purpose of describing embodiments only and is not intended to be limiting of the invention. As used herein, the singular forms are intended to include the plural forms as well, unless the context clearly indicates otherwise. It will be further understood that the terms “comprises” and/or “comprising”, when used herein, specify the presence of stated components, operations, and/or elements, but do not preclude the presence or addition of one or more other components, operations, and/or elements. In the embodiments provided below, the order of the reference numerals given in the description is not limited thereto.

Additionally, the embodiments herein will be described with reference to cross-sectional views and/or plan views as ideal exemplary views of the present invention. In the drawings, the thickness of films and regions are exaggerated for effective description of the technical contents. Accordingly, shapes of the exemplary views may be modified according to manufacturing techniques and/or allowable errors. Therefore, the embodiments of the inventive concept are not limited to the specific shape illustrated in the views, but may include other shapes created according to manufacturing processes.

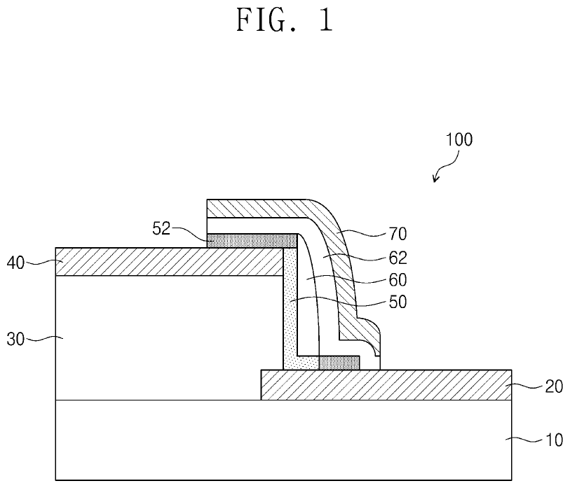

FIG. 1 illustrates an example of a thin film transistor 100 according to an embodiment of the inventive concept.

Referring to FIG. 1, the thin film transistor 100 according to an embodiment of the inventive concept may include a vertical channel oxide semiconductor thin-film transistor. The thin film transistor 100 according to an embodiment of the inventive concept may be a top gate thin-film transistor. According to an embodiment, the thin film transistor 100 according to an embodiment of the inventive concept may include a substrate 10, a data electrode 20, a spacer layer 30, a drain electrode 40, an active layer 50, impurity regions 52, a gate insulation film 60, a doped layer 62, and a gate electrode 70.

The substrate 10 may be flat. The substrate 10 may include a plastic flexible substrate or a transparent glass.

The data electrode 20 may be provided on one side of the substrate 10. The data electrode 20 may include a metal such as gold (Au), silver (Ag), copper (Cu), aluminum (Al), tungsten (W), molybdenum (Mo), cobalt (Co), or manganese (Mn), and an embodiment of the inventive concept is not limited thereto.

The spacer layer 30 may be provided on a portion of the data electrode 20 and the other side of the substrate 10. The spacer layer 30 may have a thickness greater than a thickness of the data electrode 20. The spacer layer 30 may include a dielectric of silicon oxide or silicon nitride.

The drain electrode 40 may be provided on a top surface of the spacer layer 30. The drain electrode 40 may include the same metal as the data electrode 20. The drain electrode 40 may include gold (Au), silver (Ag), copper (Cu), aluminum (Al), tungsten (W), molybdenum (Mo), cobalt (Co), or manganese (Mn), and an embodiment of the inventive concept is not limited thereto.

The active layer 50 may be provided on a sidewall of each of the drain electrode 40 and the spacer layer 30. The active layer 50 may be a channel layer having a vertical direction with respect to a horizontal plane of the substrate 10. The active layer 50 may be provided on a portion of the data electrode 20. For example, the active layer 50 may include an indium gallium zinc oxide (InGaZnO). The active layer 50 may include an indium gallium phosphorus oxide (InGaPO) or an indium gallium arsenic oxide (InGaAsO), and an embodiment of the inventive concept is not limited thereto.

The impurity regions 52 may be connected to both sides, respectively, of the active layer 50. The impurity regions 52 may reduce or remove contact resistance between the data electrode 20 and the active layer 50. In addition, the impurity regions 52 may reduce or remove contact resistance between the drain electrode 40 and the active layer 50. The impurity regions 52 may include the same material as the material of the active layer 50. The impurity regions 52 may include an indium gallium zinc oxide (InGaZnO), an indium gallium phosphorus oxide (InGaPO), or an indium gallium arsenic oxide (InGaAsO). Additionally, the impurity regions 52 may further contain impurities such as hydrogen ions (H⁺) or hydrogen molecules (H₂).

The gate insulation film 60 may be provided on the active layer 50 on the sidewall of each of the spacer layer 30 and the drain electrode 40. The gate insulation film 60 may include an insulator formed using a self-alignment method. For example, the gate insulation film 60 may include a dielectric of silicon oxide. The gate insulation film 60 may include a metal oxide such as an aluminum oxide, and an embodiment of the inventive concept is not limited thereto.

The doped layer 62 may be provided on the active layer 50 and the impurity regions 52. The doped layer 62 may include a silicon oxide containing hydrogen ions or hydrogen molecules. The doped layer 62 may diffuse the hydrogen ions or hydrogen molecules into the impurity regions 52.

The gate electrode 70 may be provided on the doped layer 62. The gate electrode 70 may supply an electric field to the active layer 50 to induce a channel in the active layer 50. The gate electrode 70 may include a metal such as gold (Au), silver (Ag), copper (Cu), aluminum (Al), tungsten (W), molybdenum (Mo), cobalt (Co), or manganese (Mn), and an embodiment of the inventive concept is not limited thereto.

A method of manufacturing the thin film transistor 100 configured thus according to an embodiment of the inventive concept is described as follows.

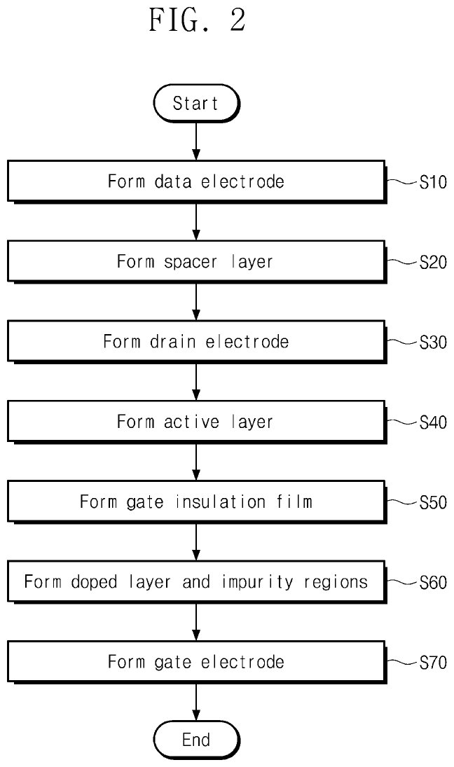

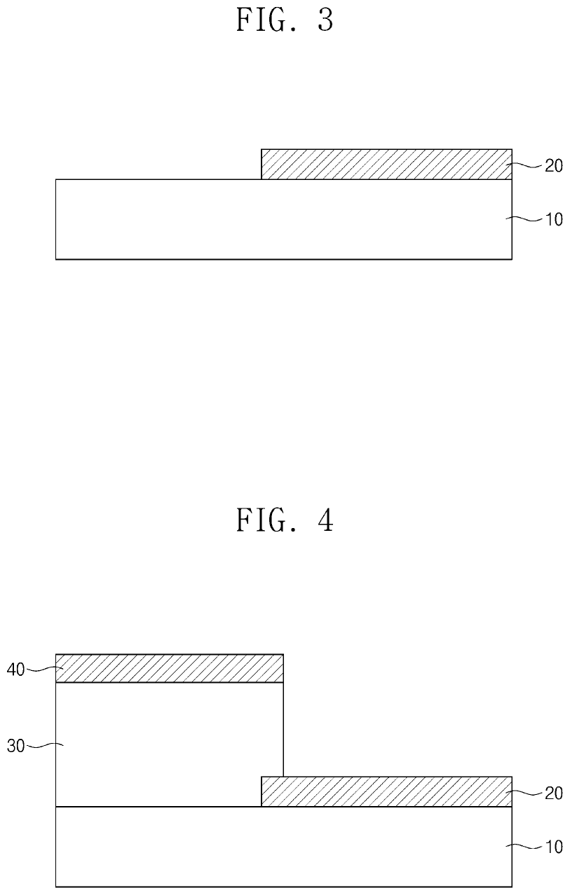

FIG. 2 is a flowchart illustrating the method of manufacturing the thin film transistor 100 in FIG. 1. FIGS. 3 to 7 are cross-sectional views illustrating operations of the method of manufacturing the thin film transistor 100 in FIG. 1.

Referring to FIGS. 2 and 3, a data electrode 20 is formed on one side of a substrate 10 (S10). The data electrode 20 may include a metal thin film formed using a physical vapor deposition method or a chemical vapor deposition method. The data electrode 20 may be formed by performing a photolithography process and an etching process on the metal thin film.

Referring to FIGS. 2 and 4, a spacer layer 30 is formed on a portion of the data electrode 20 and the other side of the substrate 10 (S20), and a drain electrode 40 is formed on the spacer layer 30 (S30).

First, the spacer layer 30 may be formed on the data electrode 20 and the substrate 10. The spacer layer 30 may include a silicon oxide formed using a chemical vapor deposition method and an atomic layer deposition method.

Then, the drain electrode 40 may be formed on the spacer layer 30. The drain electrode 40 may include a metal layer formed using a physical vapor deposition method or a chemical vapor deposition method.

The spacer layer 30 and the drain electrode 40 may be patterned through a photolithography process and an etching process at the same time. Each of the spacer layer 30 and the drain electrode 40 may have a sidewall that is provided on the data electrode 20.

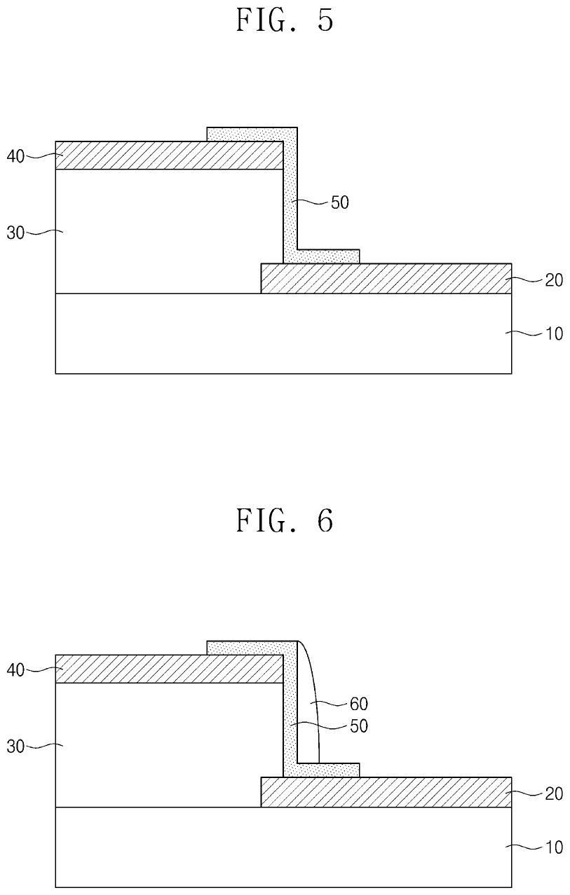

Referring to FIGS. 2 and 5, an active layer 50 may be formed on the sidewall of the spacer layer 30, the data electrode 20, and a portion of the drain electrode 40 (S40). The active layer 50 may be conformally formed on the substrate 10 to have a uniform thickness. The active layer 50 may include an indium gallium zinc oxide (InGaZnO), indium gallium phosphorus oxide (InGaPO), or indium gallium arsenic oxide (InGaAsO) formed using a physical vapor deposition method or a chemical vapor deposition method.

Referring to FIGS. 2 and 6, a gate insulation film 60 is formed on the sidewall of each of the drain electrode 40 and the spacer layer 30 (S50). The gate insulation film 60 may be selectively formed on the sidewall of each of the spacer layer 30 and the drain electrode 40 using a self-alignment method. The gate insulation film 60 may have a circular arc shape. The gate insulation film 60 may include a silicon oxide formed using a physical vapor deposition method or a rapid thermal processing method.

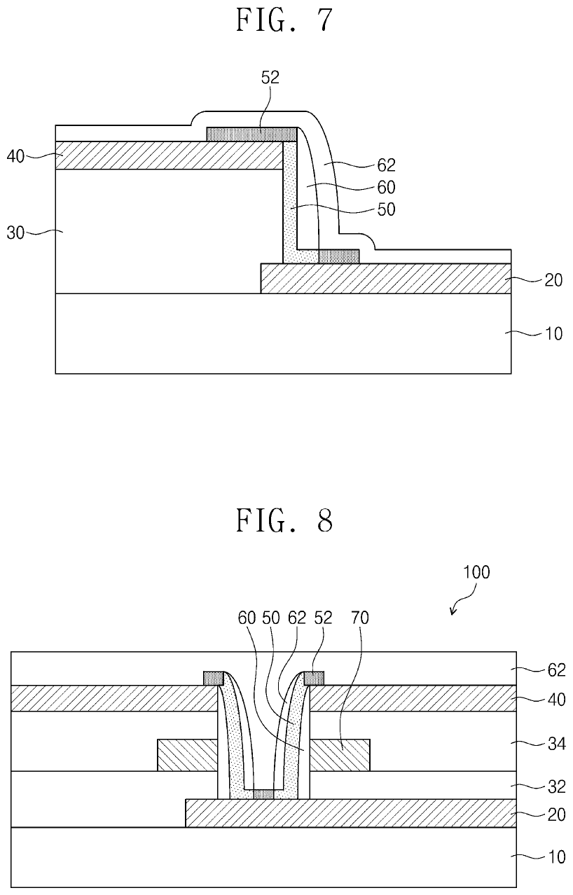

Referring to FIGS. 2 and 7, a doped layer 62 is formed on the gate insulation film 60 and the active layer 50 at each of both sides of the gate insulation film 60 to form impurity regions 52 (S60). Due to the doped layer 62, a photolithography process and an ion implantation process for doping impurities into the active layer 50 at each of the both sides of the gate insulation film 60 may be canceled. The doped layer 62 may include a silicon oxide formed using a plasma enhanced chemical vapor deposition (PECVD) method. In addition, the doped layer 62 may include a metal oxide or silicon oxide formed using a physical vapor deposition method, and an embodiment of the inventive concept is not limited thereto.

Thus, the method of manufacturing the thin film transistor 100 according to an embodiment of the inventive concept may increase productivity by using the gate insulation film 60 and the doped layer 62 to remove the photolithography process and ion implantation process for impurity doping.

Referring to FIGS. 1 and 2, a gate electrode 70 is formed on the doped layer 62 (S70). The gate electrode 70 may include a metal formed using a physical vapor deposition method or a chemical vapor deposition method. The doped layer 62 and the gate electrode 70 may be patterned through a photolithography process and an etching process.

FIG. 8 illustrates an example of a thin film transistor 100 according to an embodiment of the inventive concept.

Referring to FIG. 8, the thin film transistor 100 according to an embodiment of the inventive concept may include a bottom gate transistor.

A first spacer layer 32 and a second spacer layer 34 may be provided on a portion of a data electrode 20 and the other side of a substrate 20. The first spacer layer 32 and the second spacer layer 34 may include a silicon oxide or a silicon nitride.

A gate electrode 70 may be provided between the first spacer layer 32 and the second spacer layer 34. The gate electrode 70 may have a sidewall that is coplanar with a sidewall of each of the first spacer layer 32 and the second spacer layer 34. A drain electrode 40 may be disposed on the second spacer layer 34.

A gate insulation film 60 may be provided on a sidewall of each of the first spacer layer 32, the gate electrode 70, the second spacer layer 34, and the drain electrode 40.

An active layer 50 may be provided on a portion of each of the data electrode 20 and the drain electrode 40, and the gate insulation film 60.

Impurity regions 52 may be connected to both sides, respectively, of the active layer 50. One of the impurity regions 52 may be provided between the data electrode 20 and a doped layer 62. The other of the impurity regions 52 may be provided between the drain electrode 40 and the doped layer 62.

A doped barrier layer 64 may be provided between the active layer 50 and the doped layer 62. The doped barrier layer 64 may insulate the active layer 50 and the doped layer 62 from each other. The doped barrier layer 64 may remove or prevent impurity diffusion into the doped layer 62. For example, the doped barrier layer 64 may include a metal oxide. Alternatively, the doped barrier layer 64 may include a dielectric of silicon nitride, and an embodiment of the inventive concept is not limited thereto.

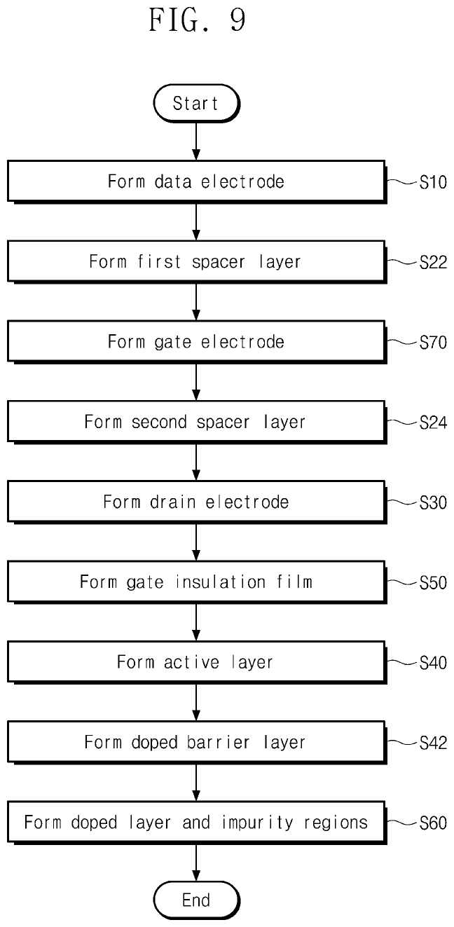

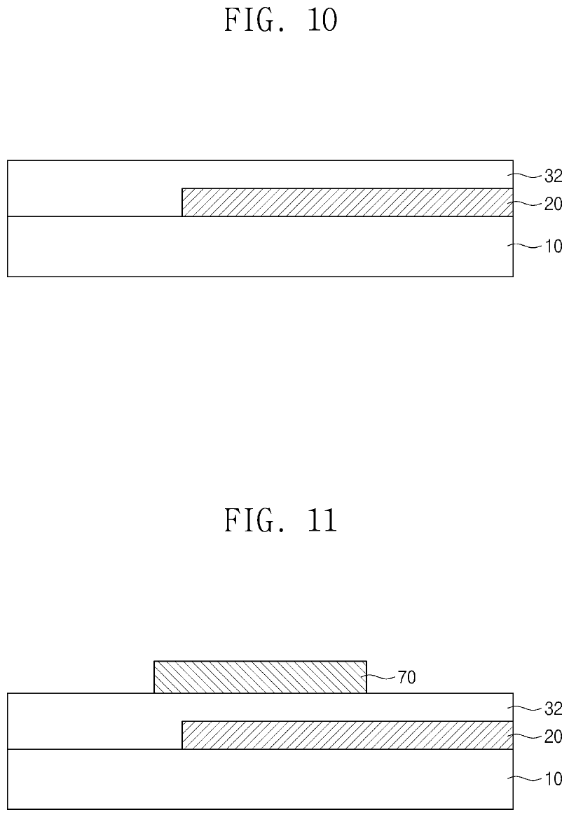

FIG. 9 is a flowchart illustrating a method of manufacturing the thin film transistor 100 in FIG. 8. FIGS. 10 to 15 are cross-sectional views illustrating operations of the method of manufacturing the thin film transistor 100 in FIG. 8.

Referring to FIGS. 9 and 10, a data electrode 20 is formed on a substrate 10 (S10).

Referring to FIGS. 9 and 11, a first spacer layer 32 is formed (S22). The first spacer layer 32 may be formed on the data electrode 20 and the substrate 10. The first spacer layer 32 may include a dielectric of silicon oxide or silicon nitride formed using a chemical vapor deposition method.

Referring to FIGS. 9 and 11 again, a gate electrode 70 is formed on the first spacer layer 32 (S70). The gate electrode 70 may include a metal layer formed using a physical vapor deposition method or a chemical vapor deposition method. The gate electrode 70 may be patterned through a photolithography process and an etching process.

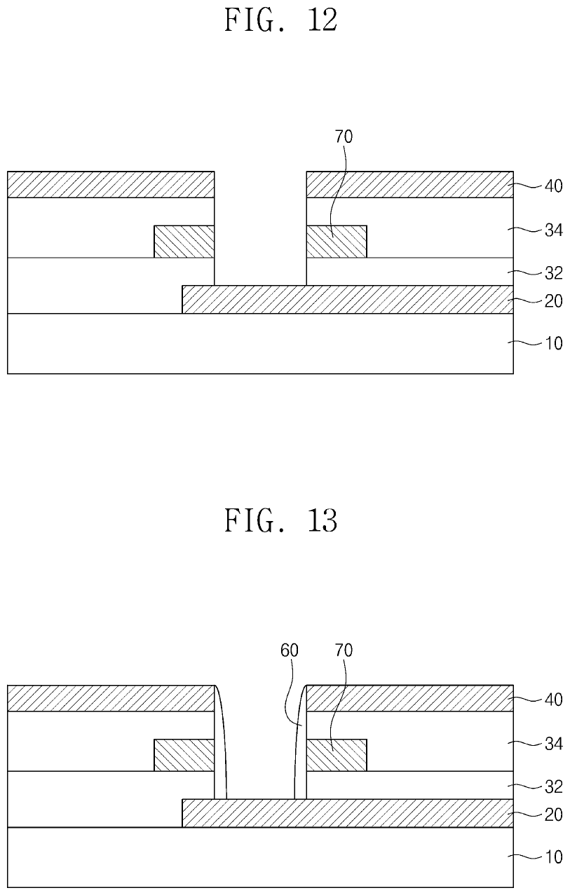

Referring to FIGS. 9 and 12, a second spacer layer 34 is formed on the gate electrode 70 and the first spacer layer 32 (S24). The second spacer layer 34 may include a dielectric of silicon oxide or silicon nitride formed using a chemical vapor deposition method.

Then, a drain electrode 40 is formed on the second spacer layer 34 (S30). The drain electrode 40 may include a metal formed using a physical vapor deposition method or a chemical vapor deposition method.

Referring to FIGS. 9 and 13, a gate insulation film 60 is formed on a sidewall of each of the first spacer layer 32, the gate electrode 70, the second spacer layer 34, and the drain electrode 40, and a portion of the data electrode 20 (S50). The gate insulation film 60 may include a silicon oxide or aluminum oxide formed using a self-alignment method. The self-alignment method may include deposition for a silicon oxide or aluminum oxide and anisotropic etching process for the silicon oxide or aluminum oxide. The anisotropic etching may include dry etching.

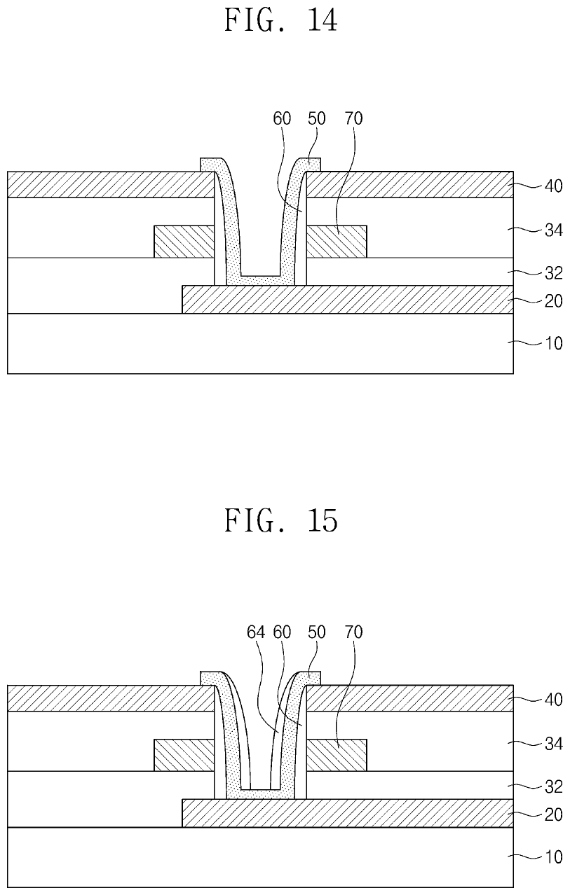

Referring to FIGS. 9 and 14, an active layer 50 is formed on a portion of each of the data electrode 20 and the drain electrode 40, and the gate insulation film 60 (S40). The active layer 50 may include an indium gallium zinc oxide (InGaZnO), indium gallium phosphorus oxide (InGaPO), or indium gallium arsenic oxide (InGaAsO) formed using a physical vapor deposition method or a chemical vapor deposition method. The active layer 50 may be patterned through a photolithography process and an etching process.

Referring to FIGS. 9 and 15, a doped barrier layer 64 is formed on a sidewall of the active layer 50 (S42). The doped barrier layer 64 may include a silicon nitride or metal oxide formed using a self-alignment method. The doped barrier layer 64 may be formed on the sidewall of the active layer 50 through anisotropic etching. The doped barrier layer 64 may have a circular arc shape.

Referring to FIGS. 8 and 9, a doped layer 62 is formed on the doped barrier layer 64, the active layer 50, and the drain electrode 40 to form impurity regions 52 (S60). The doped layer 62 may include a silicon oxide formed using a plasma enhanced chemical vapor deposition method. The doped layer 62 may contain hydrogen ions or hydrogen molecules. The impurity regions 52 may be formed on the active layer 50 exposed by the doped barrier layer 64. That is, the impurity regions 52 may be formed in both sides of the active layer 50 outside the doped barrier layer 64. The impurity regions 52 may contain the hydrogen ions or the hydrogen molecules diffused from the doped layer 62.

As described above, the method of manufacturing the thin film transistor according to an embodiment of the inventive concept may use the gate insulation film, which selectively covers the active layer on the sidewall of the spacer layer, and the doped layer on the impurity regions at the both sides of the active layer, thereby removing the photolithography process and ion implantation process for impurity doping to improve the productivity.

Although the embodiments of the present invention have been described with reference to the accompanying drawings, it is understood that the present invention should not be limited to these embodiments but various changes and modifications can be made by one ordinary skilled in the art without changing the technical idea or essential features. Therefore, it should be understood that the embodiments described above are intended to be illustrative and not for purposes of limitation in all aspects.

What is claimed is:

1. A thin film transistor manufacturing method comprising:
forming a data electrode on one side of a substrate;
forming a spacer layer on a portion of the data electrode and the other side of the substrate;
forming a drain electrode on a top surface of the spacer layer;
forming an active layer on a sidewall of the spacer layer, the drain electrode, and the data electrode;
forming a gate insulation film exposing the active layer on the drain electrode and the data electrode and covering the active layer on the sidewall of the spacer layer; and
forming a doped layer on the gate insulation film and the active layer outside the gate insulation film to form impurity regions at both sides, respectively, of the active layer.

2. The thin film transistor manufacturing method of claim 1, wherein the gate insulation film is formed using a self-alignment method.

3. The thin film transistor manufacturing method of claim 1, wherein the gate insulation film comprises a silicon oxide.

4. The thin film transistor manufacturing method of claim 1, wherein the doped layer comprises a metal oxide or semiconductor oxide containing hydrogen ions or hydrogen molecules.

5. The thin film transistor manufacturing method of claim 4, wherein the metal oxide comprises an aluminum oxide.

6. The thin film transistor manufacturing method of claim 4, wherein the semiconductor oxide comprises a silicon oxide.

7. The thin film transistor manufacturing method of claim 1, wherein the impurity regions contain hydrogen ions or hydrogen molecules.

8. The thin film transistor manufacturing method of claim 1, wherein the spacer layer comprises a silicon oxide or a silicon nitride.

9. The thin film transistor manufacturing method of claim 1, wherein the active layer comprises an indium gallium zinc oxide.

10. The thin film transistor manufacturing method of claim 1, further comprising forming a gate electrode on the doped layer.

11. A thin film transistor manufacturing method comprising:
forming a data electrode on one side of a substrate;
forming a first spacer layer on a portion of the data electrode and the other side of the substrate;
forming a gate electrode on a top surface of the first spacer layer;
forming a second spacer layer on the gate electrode and the first spacer layer;
forming a drain electrode on a top surface of the second spacer layer;
forming a gate insulation film on a sidewall of each of the first spacer layer, the gate electrode, the second spacer layer, and the drain electrode, and the data electrode;
forming an active layer on the gate insulation film, the data electrode, and the drain electrode;
forming a doped barrier layer exposing the active layer on the drain electrode and the data electrode and covering the active layer on the spacer layers; and
forming a doped layer on the doped barrier layer, the active layer outside the doped barrier layer, and the drain electrode to form impurity regions in the active layer outside the doped barrier layer.

12. The thin film transistor manufacturing method of claim 11, wherein the gate insulation film is formed using a self-alignment method.

13. The thin film transistor manufacturing method of claim 11, wherein the doped barrier layer is formed using a self-alignment method.

14. The thin film transistor manufacturing method of claim 11, wherein the doped barrier layer comprises a silicon nitride or a metal oxide.

15. The thin film transistor manufacturing method of claim 11, wherein the impurity regions contain hydrogen ions or hydrogen molecules.

16. A thin film transistor comprising:
a data electrode disposed on one side of a substrate;
a spacer layer disposed on a portion of the data electrode and the other side of the substrate;
a drain electrode on a top surface of the spacer layer;
an active layer on a sidewall of each of the spacer layer and the drain electrode, and the data electrode;
a gate insulation film disposed on an upper portion or lower portion of the active layer on the sidewall of each of the spacer layer and the drain electrode;
impurity regions, each of which is connected to the active layer at each of both sides of the gate insulation film; and
a doped layer disposed on the impurity regions and the active layer.

17. The thin film transistor of claim 16, further comprising a gate electrode disposed on the doped layer.

18. The thin film transistor of claim 16, wherein the spacer layer comprises:
a first spacer layer; and
a second spacer layer disposed on the first spacer layer.

19. The thin film transistor of claim 16, further comprising a gate electrode disposed between the first spacer layer and the second spacer layer.

20. The thin film transistor of claim 16, further comprising a doped barrier layer disposed between the active layer and the doped layer that are between the impurity regions.
